(19) United States
(12) Patent Application Publication
(10) Pub. No.: US 2025/0126934 A1
(43) Pub. Date: Apr. 17, 2025

(54) MANUFACTURING METHOD OF A LIGHT-EMITTING DEVICE AND LIGHT-EMITTING DEVICE

(71) Applicant: Enkris Semiconductor, Inc., Suzhou (CN)

(72) Inventor: Kai Cheng, Suzhou (CN)

(21) Appl. No.: 18/426,986

(22) Filed: Jan. 30, 2024

(30) Foreign Application Priority Data
Oct. 11, 2023 (CN) 202311315423.8

(51) Int. Cl. H01L 33/32; H01L 25/075; H01L 33/00

(52) U.S. Cl. CPC H10H 20/825; H01L 25/0753; H10H 20/01335

(57) ABSTRACT

A manufacturing method of a light-emitting device includes providing a substrate; forming a first mask layer on the front surface of the substrate and performing patterning process on the first mask layer to form multiple front mask openings in the first mask layer; growing a semiconductor epitaxial layer on the front surface of the substrate based on the first mask layer after patterning process and doping a first element during the growth of the semiconductor epitaxial layer to form multiple first light-emitting units and multiple second light-emitting units where the component proportion of the first element in the first light-emitting units is different from the component proportion of the first element in the second light-emitting units; turning the substrate upside down on a transposition substrate to expose the back surface of the substrate; and forming multiple third light-emitting units on the back surface of the substrate.

### CROSS-REFERENCE TO RELATED APPLICATION(S)

This application claims priority to Chinese Patent Application No. 202311315423.8 filed Oct. 11, 2023, the disclosure of which is incorporated herein by reference in its entirety.

### TECHNICAL FIELD

Embodiments of the present disclosure relate to the field of semiconductor technology and, in particular, to a manufacturing method of a light-emitting device and light-emitting device.

### BACKGROUND

Micro-led uses a blue light-emitting structure to excite red and green quantum dots to implement full-color display. Compared with conventional LED display, the Micro-led has higher image brightness, higher image contrast, richer dark field details, and more accurate color restoration.

In the related art, the light-emitting layer in an LED is implemented by wavelength conversion using phosphor powder or quantum dots. The disadvantages of this method are that the phosphor powder or quantum dots have a short service life, and there is a problem in light conversion efficiency. Furthermore, monochromatic LEDs are separately manufactured and then transferred to a driving substrate. The process is cumbersome. As a result, the yield of the obtained product is low.

### SUMMARY

Embodiments of the present disclosure provide a manufacturing method of a light-emitting device and a light-emitting device.

According to an aspect of the present disclosure, a manufacturing method of a light-emitting device is provided. The method includes the steps below.

A substrate is provided. The substrate includes a front surface and a back surface opposite to each other.

A first mask layer is formed on the front surface of the substrate. Patterning process is performed on the first mask layer to form multiple front mask openings in the first mask layer.

A semiconductor epitaxial layer is grown on the front surface of the substrate based on the first mask layer after patterning process. A first element is doped during the growth of the semiconductor epitaxial layer to form multiple first light-emitting units and multiple second light-emitting units. The component proportion of the first element in the first light-emitting units is different from the component proportion of the first element in the second light-emitting units.

The substrate is turned upside down on a transposition substrate to expose the back surface of the substrate.

Multiple third light-emitting units are formed on the back surface of the substrate.

According to another aspect of the present disclosure, a light-emitting device is provided. The device includes a substrate, a first mask layer, multiple first light-emitting units and multiple second light-emitting units, and multiple third light-emitting units.

The substrate includes a front surface and a back surface opposite to each other.

The first mask layer includes multiple front mask openings.

The multiple first light-emitting units and multiple second light-emitting units are located on the front surface of the substrate. The component proportion of the first element in the first light-emitting units is different from the component proportion of the first element in the second light-emitting units.

The third light-emitting units are located on the back surface of the substrate.

### BRIEF DESCRIPTION OF DRAWINGS

FIG. 1 is a flowchart of a manufacturing method of a light-emitting device according to an embodiment of the present disclosure.

FIG. 2 is a flowchart of another manufacturing method of a light-emitting device according to an embodiment of the present disclosure.

FIGS. 3 to 13 are sectional views corresponding to steps S210 to S2110 in a manufacturing method of a light-emitting device according to an embodiment of the present disclosure.

FIG. 14 is a sectional view illustrating the structure of a light-emitting device according to an embodiment of the present disclosure.

FIG. 15 is a flowchart of another manufacturing method of a light-emitting device according to an embodiment of the present disclosure.

FIGS. 16 to 19 are sectional views corresponding to steps S370 to S3110 in a manufacturing method of a light-emitting device according to an embodiment of the present disclosure.

FIG. 20 is a flowchart of another manufacturing method of a light-emitting device according to an embodiment of the present disclosure.

FIGS. 21 to 29 are sectional views corresponding to steps S420 to S4110 in a manufacturing method of a light-emitting device according to an embodiment of the present disclosure.

### DETAILED DESCRIPTION

For a better understanding of the solution of the present disclosure by those skilled in the art, the technical solutions in embodiments of the present disclosure are described clearly and completely in conjunction with the drawings in the embodiments of the present disclosure. Apparently, the embodiments described are part, not all, of the embodiments of the present disclosure.

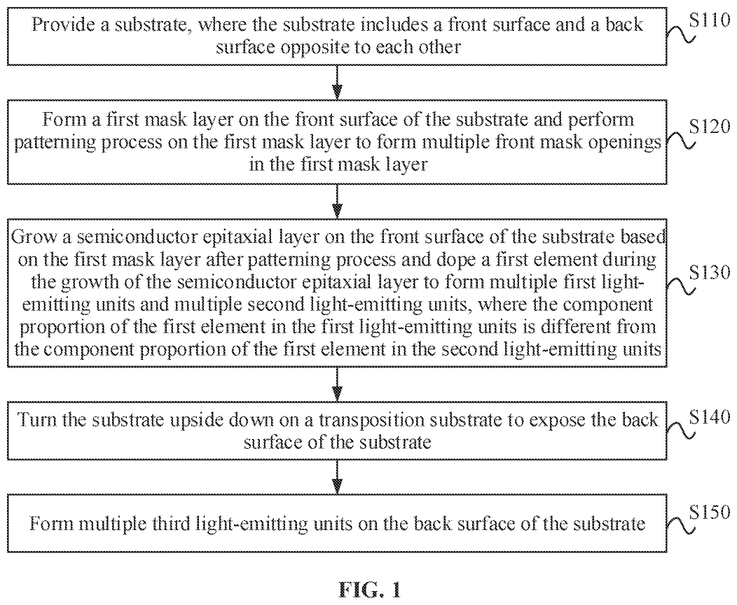

An embodiment of the present disclosure provides a manufacturing method of a light-emitting device. FIG. 1 is a flowchart of a manufacturing method of a light-emitting device according to an embodiment of the present disclosure. Referring to FIG. 1, the manufacturing method of a light-emitting device includes the steps below.

In S110, a substrate is provided. The substrate includes a front surface and a back surface opposite to each other.

Illustratively, the material of the substrate may be a material such as sapphire, silicon carbide, silicon, GaN, AlN, or diamond. This is not limited in this embodiment.

In S120, a first mask layer is formed on the front surface of the substrate. Patterning process is performed on the first mask layer to form multiple front mask openings in the first mask layer.

Illustratively, the material of the first mask layer may be nitride or oxide, such as at least one of silicon dioxide or silicon nitride. The first mask layer may be formed by physical vapor deposition or chemical vapor deposition. Patterning process may be implemented by dry etching or wet etching.

In S130, a semiconductor epitaxial layer is grown on the front surface of the substrate based on the first mask layer after patterning process. A first element is doped during the growth of the semiconductor epitaxial layer to form multiple first light-emitting units and multiple second light-emitting units. The component proportion of the first element in the first light-emitting units is different from the component proportion of the first element in the second light-emitting units.

Illustratively, the semiconductor epitaxial layer is grown on the front surface of the substrate based on the first mask layer after patterning process. The first element is doped during the growth of the semiconductor epitaxial layer to form multiple first light-emitting units and multiple second light-emitting units. There is no need to etch the front surface of the substrate. Thus, it is possible to prevent the difficulty in controlling the etching depth and position when the front surface of the substrate is etched from affecting the qualification rate of device preparation. The semiconductor epitaxial layer is grown on the front surface of the substrate. In an example, the first light-emitting units and the second light-emitting units may all be located in the front mask openings; or, part of light-emitting units may be located in front mask openings, and part of the light-emitting units may be located on the first mask layer. The component proportion of the first element in the first light-emitting units is different from the component proportion of the first element in the second light-emitting units, so that the same substrate has light-emitting units having two light-emitting wavelengths at the same time.

For example, a first light-emitting unit may be a blue light-emitting unit that emits blue light, and a second light-emitting unit may be a green light-emitting unit that emits green light. In an embodiment, if the first element is In, the component proportion of the first element in the first light-emitting units is smaller than the component proportion of the first element in the second light-emitting units. In another embodiment, if the first element is Al, the component proportion of the first element in the first light-emitting units is larger than the component proportion of the first element in the second light-emitting units. In other embodiments, other first elements may also be doped.

In S140, the substrate is turned upside down on a transposition substrate to expose the back surface of the substrate.

Illustratively, before the substrate is turned upside down on the transposition substrate, a first passivation layer may be formed on the front surface of the substrate, and the first passivation layer covers at least a surface of the first light-emitting units and the second light-emitting units to ensure that the substrate can be smoothly turned upside down on the transposition substrate, which is beneficial to subsequent processes.

In S150, multiple third light-emitting units are formed on the back surface of the substrate.

Illustratively, the emitted color of a third light-emitting unit is different from the emitted color of a first light-emitting unit and the emitted color of a second light-emitting unit. For example, the first light-emitting unit is a blue light-emitting unit, the second light-emitting unit is a green light-emitting unit, and the emitted color of the third light-emitting unit may be red.

In the manufacturing method of a light-emitting device provided by this embodiment of the present disclosure, the first mask layer is formed on the front surface of the substrate. Patterning process is performed on the first mask layer to form multiple front mask openings in the first mask layer. The first light-emitting units and multiple second light-emitting units are simultaneously prepared on the front surface of the substrate based on the first mask layer after patterning process. Thus, the production efficiency of the light-emitting device is improved, and meanwhile, there is no need to etch the substrate. Then the probability of scrapping due to excessive etching of the substrate is reduced, thereby improving the yield of device production. Moreover, the third light-emitting units are prepared on the back surface of the substrate, so that light-emitting units of different colors can be transferred to a driving substrate synchronously through the transposition substrate, thereby further improving the production yield of the light-emitting device. In addition, the first element is doped during the growth of the semiconductor epitaxial layer to form multiple first light-emitting units and multiple second light-emitting units. The components of the light-emitting layers corresponding to different positions on the front surface are controlled to be different to form the first light-emitting unit and the second light-emitting unit with different light-emitting wavelengths. There is no need to use phosphor powder or quantum dots for wavelength conversion. Thus, the service life of the light-emitting device is prolonged, and the reliability of the light-emitting device is improved.

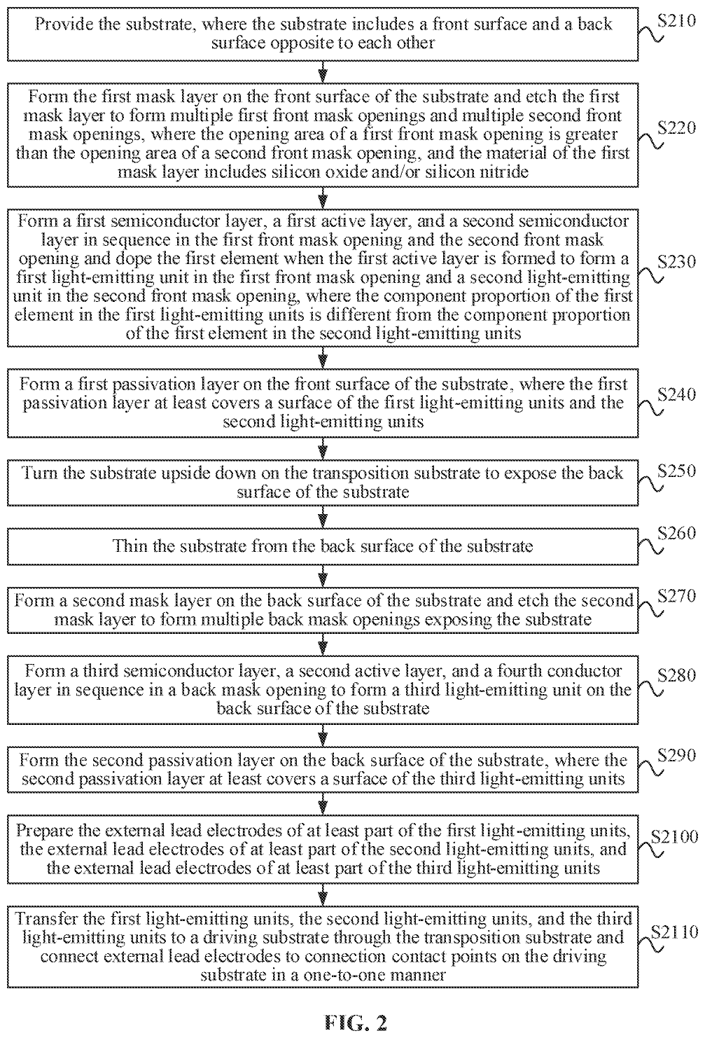

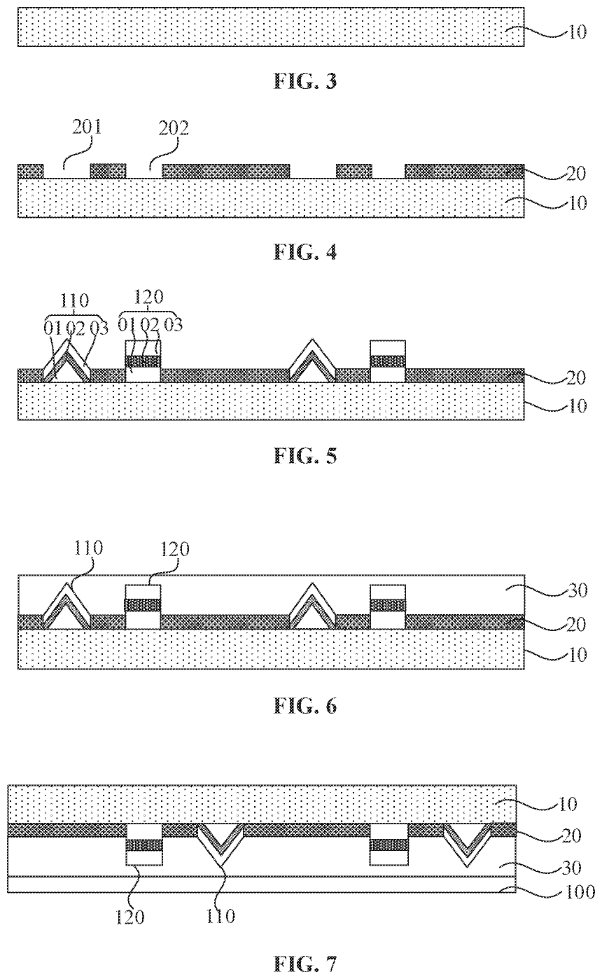

For example, FIG. 2 is a flowchart of another manufacturing method of a light-emitting device according to an embodiment of the present disclosure. FIGS. 3 to 13 are sectional views corresponding to steps S210 to S2110 in a manufacturing method of a light-emitting device according to an embodiment of the present disclosure. Referring to FIG. 2, the manufacturing method of a light-emitting device includes the steps below.

In S210, the substrate is provided. The substrate includes a front surface and a back surface opposite to each other.

Illustratively, referring to FIG. 3, the material of the substrate 10 may be a material such as sapphire, silicon carbide, silicon, GaN, AlN, or diamond. This is not limited in this embodiment.

In S220, the first mask layer is formed on the front surface of the substrate, and the first mask layer is etched to form multiple first front mask openings and multiple second front mask openings. The opening area of a first front mask opening is greater than the opening area of a second front mask opening. The material of the first mask layer includes silicon oxide and/or silicon nitride.

Illustratively, referring to FIG. 4, the first mask layer 20 is etched to form multiple first front mask openings 201 and multiple second front mask openings 202. The opening area of a first front mask opening 201 is greater than the opening area of a second front mask opening 202.

In S230, a first semiconductor layer, a first active layer, and a second semiconductor layer are formed in sequence in the first front mask opening and the second front mask opening. A first element is doped when the first active layer is formed to form a first light-emitting unit in the first front mask opening and a second light-emitting unit in the second front mask opening. The component proportion of the first element in the first light-emitting units is different from the component proportion of the first element in the second light-emitting units.

Illustratively, referring to FIG. 5, the material of the first semiconductor layer 01 may be group III nitride and may include at least one of GaN or AlGaN. The material of the second semiconductor layer 03 may be group III nitride and may include at least one of GaN or AlGaN. Optionally, the first semiconductor layer 01 may be a p-type semiconductor layer, and the second semiconductor layer 03 may be an n-type semiconductor layer; or, the first semiconductor layer 01 may be an n-type semiconductor layer, and the second semiconductor layer 03 may be a p-type semiconductor layer.

The first active layer 02 may include at least one of a single quantum well structure, a multi-quantum well (MQW) structure, a quantum wire structure, or a quantum dot structure. The material of the first active layer 02 may be a GaN-based material, which may be doped with In element, for example, InGaNin; and may also be doped with Al element, for example, AlGaN. The band gap of InN is about 0.7 eV and is smaller than the band gap of GaN, where the band gap of GaN is 3.4 eV. Thus, the larger the doping amount of In is, the longer the emission wavelength of the first active layer 02 is. The band gap of AlN is about 6.2 eV and is larger than the band gap of GaN, where the band gap of GaN is 3.4 eV. Thus, the larger the doping amount of Al is, the shorter the emission wavelength of the first active layer 02 is.

Illustratively, further referring to FIG. 5, the GaN-based material is used as an example. Based on that the area of the first front mask opening 201 is different from the area of the second front mask opening 202, when the first element is doped, the flow rate of the reaction gas in the first front mask opening 201 and the flow rate of the reaction gas in the second front mask opening 202 are different, so that the doping rate of In/Al element is different from the doping rate of Ga element, that is, the doping efficiency of In/Al element is different. Thus, the component proportion of In/Al element in the first active layer 02 in the first light-emitting unit is different from the component proportion of In/Al element in the first active layer 02 in the second light-emitting unit. Further, the wavelength of the light emitted by the first light-emitting unit 110 and the wavelength of the light emitted by the second light-emitting unit 120 are different. Each first mask opening 201 correspondingly grows a first light-emitting unit 110. Each second mask opening 202 correspondingly grows a second light-emitting unit 120. Under the same manufacturing condition, the second light-emitting unit 120 grown in the second mask opening 202 having a smaller size may be in a tetrahedral shape and emit light on a transverse plane, while the first light-emitting unit 110 grown in the first mask opening 201 having a larger size may be in a hexagonal pyramid shape and emit light on an inclined surface. The shape of the first front mask opening and the shape of the second front mask opening may be any shapes such as a circle, a square, and a hexagon.

When In element is doped in base material GaN of the first active layer 02, the smaller the opening area of a front mask opening is, the better the selectivity of the doping of In element is, so that the doping rate of In element is larger than the doping rate of Ga element. Thus, the smaller the opening area of the front mask opening is, the higher the component content of In element in InGaN of the first active layer 02 is. In addition, the smaller the opening area of the front mask opening is, the thickness of the quantum well in the groove increases accordingly. Due to the quantum Stark effect, an emission wavelength may increase accordingly. On the contrary, the larger the opening area of the front mask opening is, the less significant the difference between the doping rate of In element and the doping rate of Ga element is, that is, the lower the doping efficiency of In element is, the lower the component proportion of In element in the grown first active layer 02 is. In this embodiment of the present disclosure, the opening area of a first front mask opening is greater than the opening area of a second front mask opening, that is, the component proportion of In element in a first groove is lower than the component proportion of In element in a second groove. The wavelength of the first light-emitting unit in the first groove is smaller than the wavelength of the second light-emitting unit in the second groove. The first light-emitting unit may be a blue light-emitting unit. The second light-emitting unit may be a green light-emitting unit.

When Al element is doped in base material GaN of the first active layer 02, the smaller the opening area of the front mask opening is, the less the selectivity of the growth of Al element is, so that the doping rate of Al element is smaller than the doping rate of Ga element. Thus, the smaller the opening area of the front mask opening is, the lower the component content of Al element in AlGaN of the first active layer 02 is. Thus, the smaller the doping amount of Al is, the longer the emission wavelength of the first active layer 02 is. In addition, the larger the opening area of the front mask opening is, the smaller the thickness of the grown first active layer 02 is. The smaller the opening area of the front mask opening is, the larger the thickness of the grown first active layer 02 is, and the thickness of the quantum well increases accordingly. Due to the quantum Stark effect, the emission wavelength may increase accordingly. In this embodiment of the present disclosure, the opening area of a first front mask opening is greater than the opening area of a second front mask opening, that is, the component proportion of Al element in the first groove is larger than the component proportion of Al element in the second groove. The wavelength of the first light-emitting unit in the first groove is smaller than the wavelength of the second light-emitting unit in the second groove. The first light-emitting unit may be a blue light-emitting unit. The second light-emitting unit may be a green light-emitting unit.

In S240, the first passivation layer may be formed on the front surface of the substrate. The first passivation layer covers at least a surface of the first light-emitting units and the second light-emitting units.

Illustratively, referring to FIG. 6, the first light-emitting units 110 and the second light-emitting units 120 may be protected by the first passivation layer 30 against abrasion to the first light-emitting units 110 and the second light-emitting units 120 during transposition. In addition, the surface of the first passivation layer 30 on the side far away from the substrate 10 may be a flat surface. Thus, the first passivation layer 30 may also function as planarization to ensure that the substrate 10 can be smoothly turned upside down on the transposition substrate 100, which is beneficial to subsequent processes.

In S250, the substrate is turned upside down on the transposition substrate to expose the back surface of the substrate.

Illustratively, referring to FIG. 7, the substrate 10 is turned upside down on the transposition substrate 100 to expose the back surface of the substrate 10.

In S260, the substrate is thinned from the back surface of the substrate.

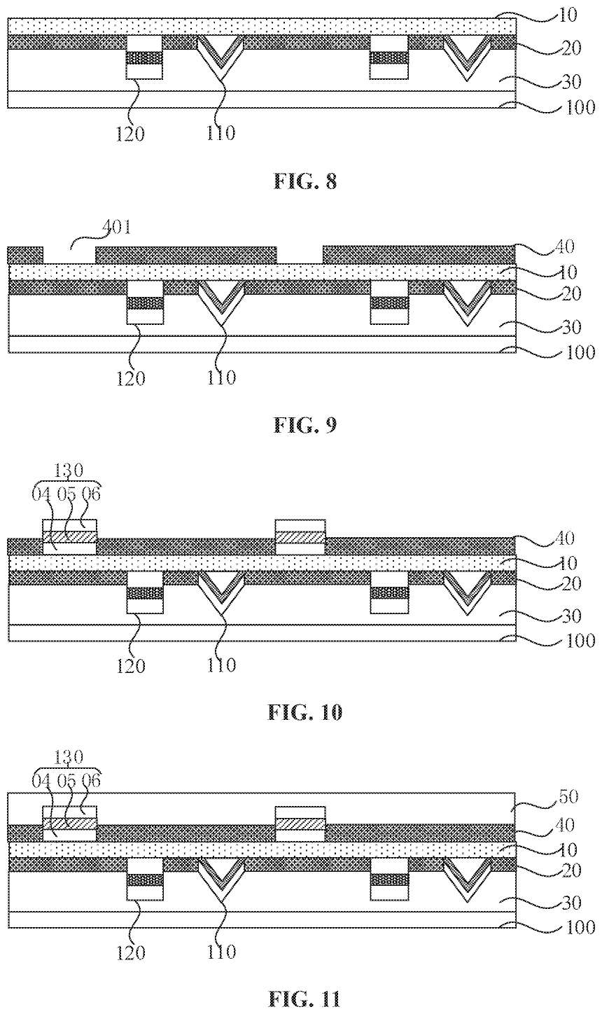

Illustratively, referring to FIG. 8, by thinning the substrate 10, the overall thickness of the light-emitting device may be reduced, which is beneficial to make the device thin and light. In addition, by thinning the substrate 10, the transparency of the substrate 10 may be improved, and the transparent display is implemented. For example, the material of the substrate 10 is sapphire, and the sapphire has good light transmittance. By thinning substrate 10, the light transmittance of the substrate 10 may be further improved, and the transparent display is implemented. The material of the substrate 10 is Si, and Si has poor light transmittance. The substrate 10 is thinned. In this manner, the light transmittance of the substrate 10 may be improved.

In S270, a second mask layer is formed on the back surface of the substrate. The second mask layer is etched to form multiple back mask openings exposing the substrate.

Illustratively, referring to FIG. 9, the second mask layer 40 is formed on the back surface of the substrate. The second mask layer 40 is etched to form multiple back mask openings 401 exposing the substrate. The second mask layer may be nitride or oxide, such as at least one of silicon dioxide or silicon nitride.

In S280, a third semiconductor layer, a second active layer, and a fourth conductor layer are formed in sequence in a back mask opening to form a third light-emitting unit on the back surface of the substrate.

Illustratively, referring to FIG. 10, the third semiconductor layer 04, the second active layer 05, and the fourth semiconductor layer 06 are formed in sequence in the back mask opening 401 to form the third light-emitting unit 130 on the back surface of the substrate. The conductivity type of the third semiconductor layer 04 is opposite to the conductivity type of the fourth semiconductor layer 06. For materials of the third semiconductor layer 04, the second active layer 05, and the fourth semiconductor layer 06, reference may be made to the preceding embodiment, and the details are not repeated here.

In S290, a second passivation layer is formed on the back surface of the substrate. The second passivation layer covers at least a surface of the third light-emitting units.

Illustratively, referring to FIG. 11, the second passivation layer 50 is formed on the back surface of the substrate. The second passivation layer 50 covers at least the surface of the third light-emitting units 130. The third light-emitting units 130 may be protected by the second passivation layer 50 against abrasion to the third light-emitting units 130 during transposition.

The material of the second passivation layer 50 may be oxide or nitride, such as at least one of silicon dioxide or silicon nitride. The second passivation layer 50 may be formed by physical vapor deposition or atomic layer deposition.

In S2100, the external lead electrodes of at least part of the first light-emitting units, the external lead electrodes of at least part of the second light-emitting units, and the external lead electrodes of at least part of the third light-emitting units are prepared.

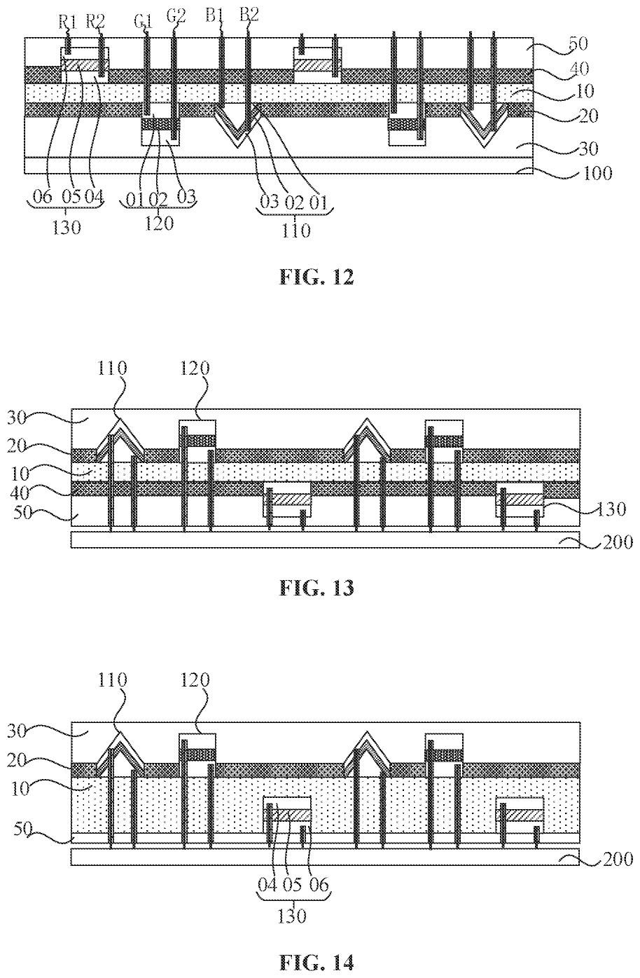

Illustratively, referring to FIG. 12, the first active layer 02 is located between the first semiconductor layer 01 and the second semiconductor layer 03. The second active layer 05 is located between the third semiconductor layer 04 and the fourth semiconductor layer 06. The external lead electrode of a first light-emitting unit 110 is prepared in the following manners: A first positive electrode hole and a first negative electrode hole are formed on the side of the first light-emitting unit 110 far away from the transposition substrate 100, where one of the first positive electrode hole and the first negative electrode hole is etched to the first semiconductor layer 01 of the first light-emitting unit 110, and the other one of the first positive electrode hole and the first negative electrode hole is etched to the second semiconductor layer 03 of the first light-emitting unit 110; and insulating layers are formed on the hole walls of the first positive electrode hole and the first negative electrode hole, and a first external positive electrode B1 is formed in the first positive electrode hole, and a first external negative electrode B2 is formed in the first negative electrode hole. Similarly, a second external positive electrode G1 electrically connected to the first semiconductor layer 01 of the second light-emitting unit 120 and a second external negative electrode G2 electrically connected to the second semiconductor layer 03 of the second light-emitting unit 120 are prepared. A third external positive electrode R1 electrically connected to the fourth semiconductor layer 06 of the third light-emitting unit 130 and a third external negative electrode R2 electrically connected to the third semiconductor layer 04 of the third light-emitting unit 130 are prepared. The vertical projection of a first light-emitting unit 110 having an external lead electrode on the transposition substrate 100, the vertical projection of a second light-emitting unit 120 having an external lead electrode on the transposition substrate 100, and the vertical projection of a third light-emitting unit 130 having an external lead electrode on the transposition substrate 100 do not overlap each other.

In S2110, the first light-emitting units, the second light-emitting units, and the third light-emitting units are transferred to the driving substrate through the transposition substrate, and external lead electrodes are connected to connection contact points on the driving substrate in a one-to-one manner.

Illustratively, referring to FIG. 13, the first light-emitting units 110, the second light-emitting units 120, and the third light-emitting units 130 are transferred to the driving substrate 200 through the transposition substrate 100, and external lead electrodes are connected to connection contact points on the driving substrate 200 in a one-to-one manner.

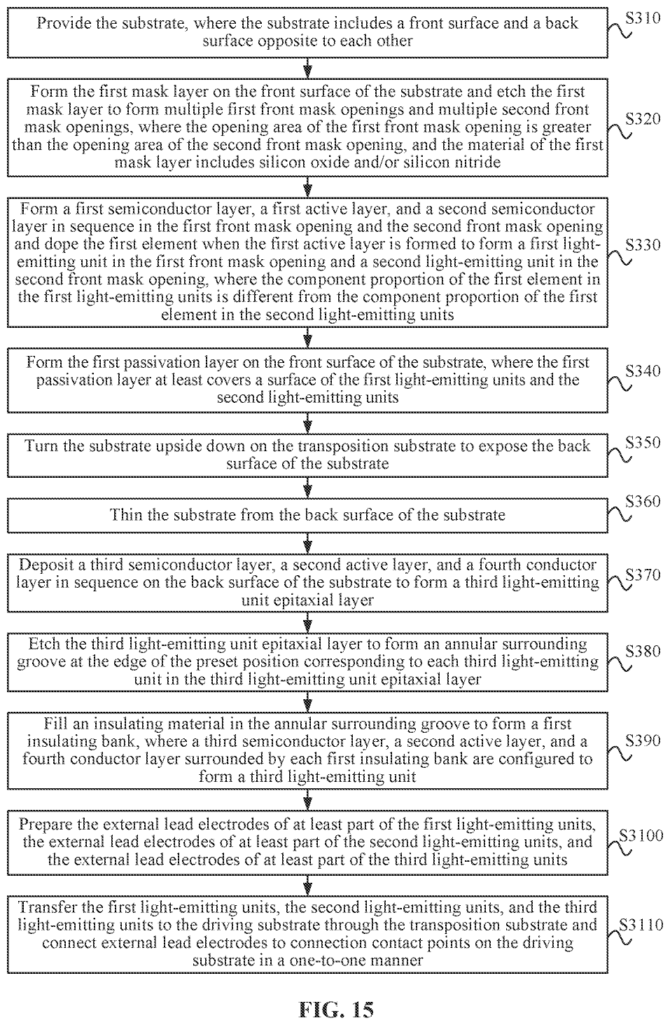

Optionally, FIG. 14 is a sectional view illustrating the structure of a light-emitting device according to an embodiment of the present disclosure. Referring to FIG. 14, multiple third light-emitting units 130 are formed on the back surface of the substrate 10 in the following manners: The back surface of the substrate 10 is etched to form multiple grooves; and a third semiconductor layer 04, a second active layer 05, and a fourth conductor layer 06 are formed in in sequence a groove to form a third light-emitting unit 130 on the back surface of the substrate.

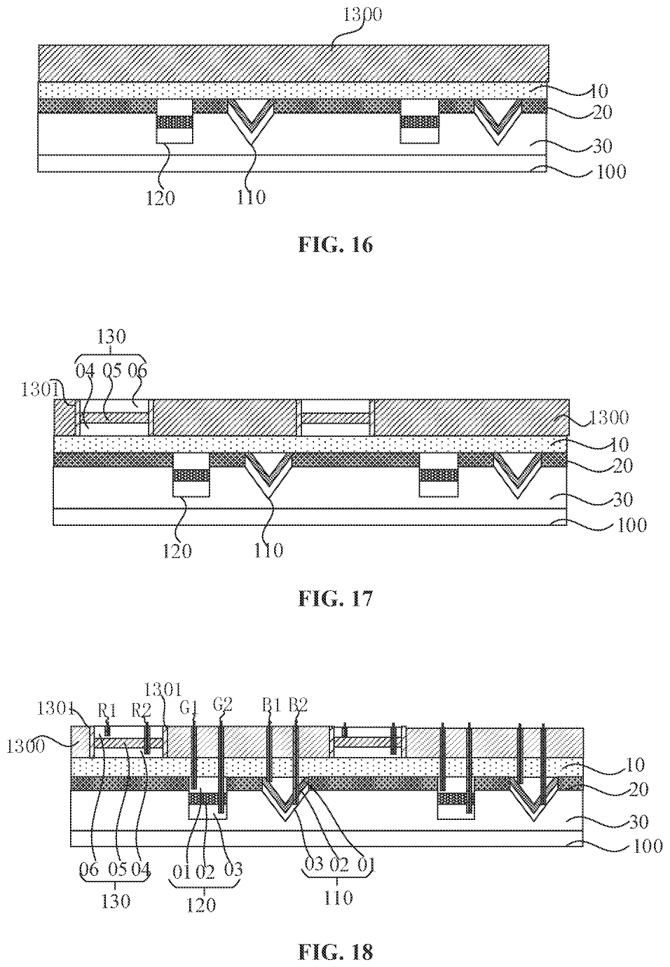

FIG. 15 is a flowchart of another manufacturing method of a light-emitting device according to an embodiment of the present disclosure. Referring to FIG. 15, FIGS. 16 to 19 are sectional views corresponding to steps S370 to S3110 in a manufacturing method of a light-emitting device according to an embodiment of the present disclosure. The manufacturing method of a light-emitting device includes the steps below.

For S310 to S360, reference may be made to steps S210 to S260. The first light-emitting units 110 and the second light-emitting units 120 are manufactured on the front surface of the substrate 10, and the details are not repeated here.

In S370, a third semiconductor layer, a second active layer, and a fourth conductor layer are deposited in sequence on the back surface of the substrate to form a third light-emitting unit epitaxial layer.

Illustratively, referring to FIG. 16, the third semiconductor layer, the second active layer, and the fourth semiconductor layer are deposited in sequence on the back surface of the substrate 10 to form the third light-emitting unit epitaxial layer 1300. Illustratively, for materials of the third semiconductor layer, the second active layer, and the fourth semiconductor layer, reference may be made to the preceding embodiment, and the details are not repeated here.

In S380, the third light-emitting unit epitaxial layer is etched to form an annular surrounding groove at the edge of the preset position corresponding to each third light-emitting unit in the third light-emitting unit epitaxial layer.

In S390, an insulating material is filled in the annular surrounding groove to form a first insulating bank. A third semiconductor layer, a second active layer, and a fourth semiconductor layer surrounded by each first insulating bank are configured to form a third light-emitting unit.

Illustratively, referring to FIG. 17, the insulating material is filled in the annular surrounding groove to form the first insulating bank 1301. The third semiconductor layer 04, the second active layer 05, and the fourth semiconductor layer 06 surrounded by each first insulating bank 1301 are configured to form a third light-emitting unit 130.

In S3100, the external lead electrodes of at least part of the first light-emitting units, the external lead electrodes of at least part of the second light-emitting units, and the external lead electrodes of at least part of the third light-emitting units are prepared.

Illustratively, referring to FIG. 18, a first external lead positive electrode B1 and a first external lead negative electrode B2 of the first light-emitting unit 110 are prepared; a second external lead positive electrode G1 and a second external lead negative electrode G2 of the second light-emitting unit 120 are prepared; a third external lead positive electrode R1 and a third external lead negative electrode R2 of the third light-emitting unit 130 are prepared. For the preparation process, reference may be made to step S2100, and the details are not repeated here.

In S3110, the first light-emitting units, the second light-emitting units, and the third light-emitting units are transferred to the driving substrate through the transposition substrate, and external lead electrodes are connected to connection contact points on the driving substrate in a one-to-one manner.

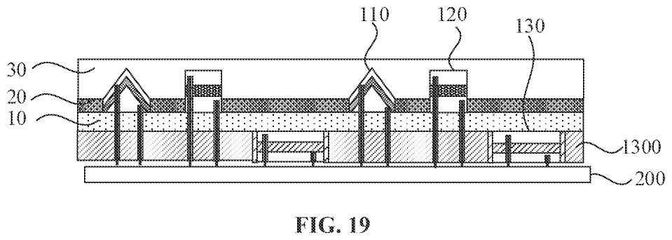

Illustratively, referring to FIG. 19, the first light-emitting units 110, the second light-emitting units 120, and the third light-emitting units 130 are transferred to the driving substrate 200 through the transposition substrate 100, and external lead electrodes are connected to connection contact points on the driving substrate 200 in a one-to-one manner.

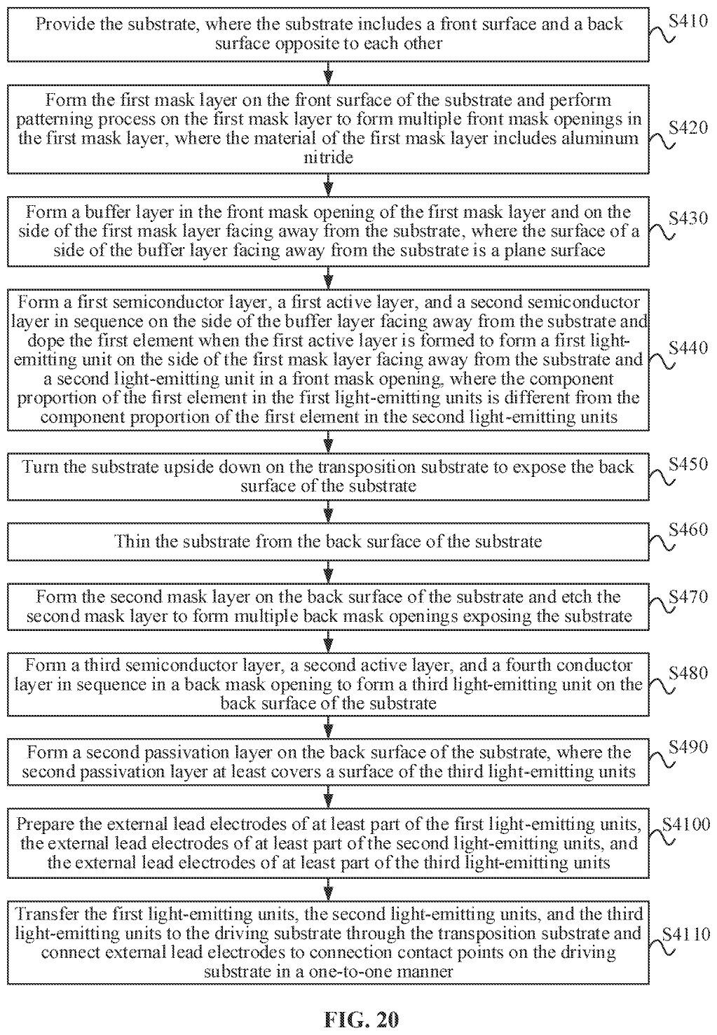

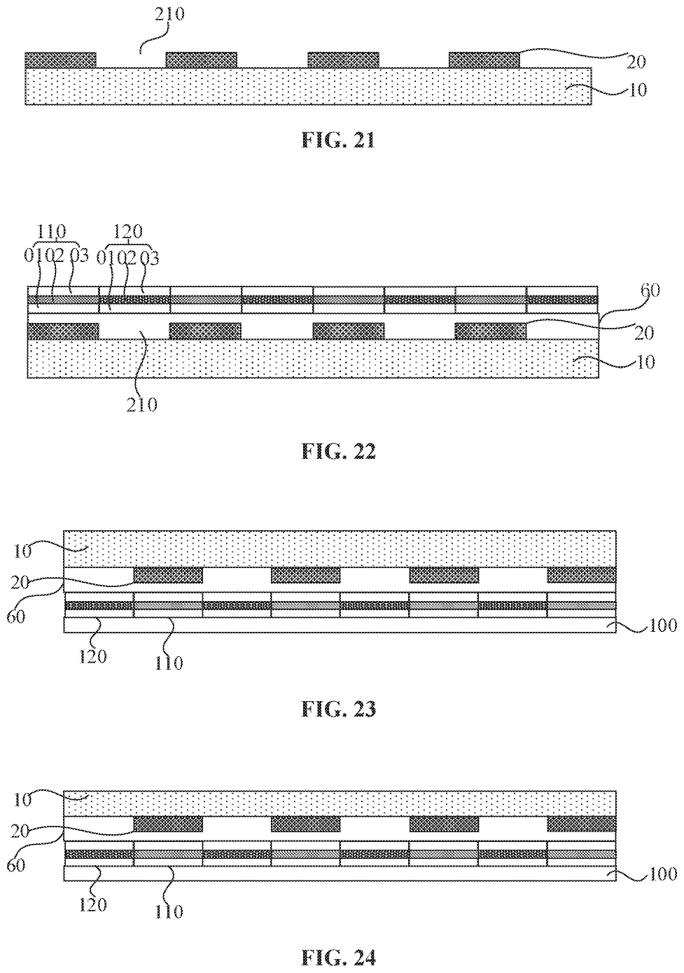

FIG. 20 is a flowchart of another manufacturing method of a light-emitting device according to an embodiment of the present disclosure. FIGS. 21 to 29 are sectional views corresponding to steps S420 to S4110 in a manufacturing method of a light-emitting device according to an embodiment of the present disclosure. Referring to FIG. 20, the manufacturing method of a light-emitting device includes the steps below.

In S410, the substrate is provided. The substrate includes a front surface and a back surface opposite to each other. Illustratively, reference may be made to step S210, and the details are not repeated here.

In S420, the first mask layer is formed on the front surface of the substrate. Patterning process is performed on the first mask layer to form multiple front mask openings in the first mask layer. The material of the first mask layer includes aluminum nitride.

Illustratively, referring to FIG. 21, the material of the first mask layer 20 includes aluminum nitride, which may function as stress adjustment. Patterning process is performed on the first mask layer 20 to form multiple front mask openings 210 in the first mask layer 20.

In S430, a buffer layer is formed in the front mask opening of the first mask layer and on the side of the first mask layer facing away from the substrate. The surface of the buffer layer on the side facing away from the substrate is a plane surface.

In S440, a first semiconductor layer, a first active layer, and a second semiconductor layer are formed in sequence on the side of the buffer layer facing away from the substrate. A first element is doped when the first active layer is formed to form a first light-emitting unit on the side of the first mask layer facing away from the substrate and a second light-emitting unit in a front mask opening. The component proportion of the first element in the first light-emitting units is different from the component proportion of the first element in the second light-emitting units.

Illustratively, referring to FIG. 22, the buffer layer 60 is located between the substrate 10 and light-emitting units. The buffer layer 60 is configured to effectively improve the crystal quality of the light-emitting units and improve the light-emitting efficiency. The surface of the buffer layer 60 on the side facing away from the substrate 10 is a plane surface, so that the height of a first light-emitting unit 110 and the height of a second light-emitting unit 120 located on the front surface of the substrate are the same. Illustratively, the material of the first mask layer is AlN. Since the lattice constant of the first mask layer is smaller than the lattice constant of the light-emitting units, the first light-emitting unit on the first mask layer has a built-in stress different from the built-in stress of the second light-emitting unit in a front mask opening. Further, the first light-emitting unit 110 on the first mask layer 20 has a built-in stress different from the built-in stress of the second light-emitting unit 120 in the front mask opening 210. Thus, the component of the first element in the first light-emitting units 110 is smaller than the component of the first element in the second light-emitting units 120, so that the same substrate has light-emitting units having two light-emitting wavelengths at the same time.

In S450, the substrate is turned upside down on the transposition substrate to expose the back surface of the substrate.

Illustratively, referring to FIG. 23, the substrate 10 is turned upside down on the transposition substrate 100 to expose the back surface of the substrate 10.

In S460, the substrate is thinned from the back surface of the substrate.

Illustratively, referring to FIG. 24, the substrate 10 is thinned from the back surface of the substrate 10. For the effect of thinning the substrate 10, reference may be made to step S260, and the details are not repeated here.

In S470, the second mask layer is formed on the back surface of the substrate. The second mask layer is etched to form multiple back mask openings exposing the substrate.

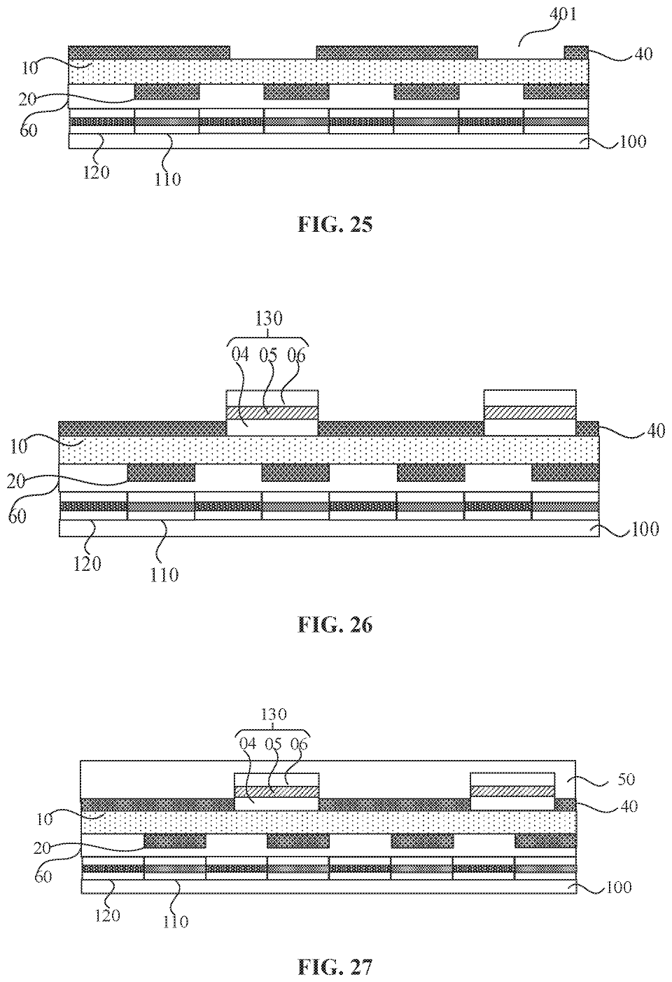

Illustratively, referring to FIG. 25, the second mask layer 40 is formed on the back surface of the substrate 10. The second mask layer 40 is etched to form multiple back mask openings 401 exposing the substrate.

In S480, the third semiconductor layer, the second active layer, and the fourth conductor layer are formed in sequence in the back mask opening to form the third light-emitting unit on the back surface of the substrate.

Illustratively, referring to FIG. 26, the third semiconductor layer, the second active layer, and the fourth semiconductor layer are formed in sequence in the back mask opening 401 to form the third light-emitting unit 130 on the back surface of the substrate.

In S490, the second passivation layer is formed on the back surface of the substrate. The second passivation layer covers at least a surface of the third light-emitting units.

Illustratively, referring to FIG. 27, the second passivation layer 50 is formed on the back surface of the substrate 10. For the function of the second passivation layer 50, reference may be made to step S290, and the details are not repeated here.

In S4100, the external lead electrodes of at least part of the first light-emitting units, the external lead electrodes of at least part of the second light-emitting units, and the external lead electrodes of at least part of the third light-emitting units are prepared.

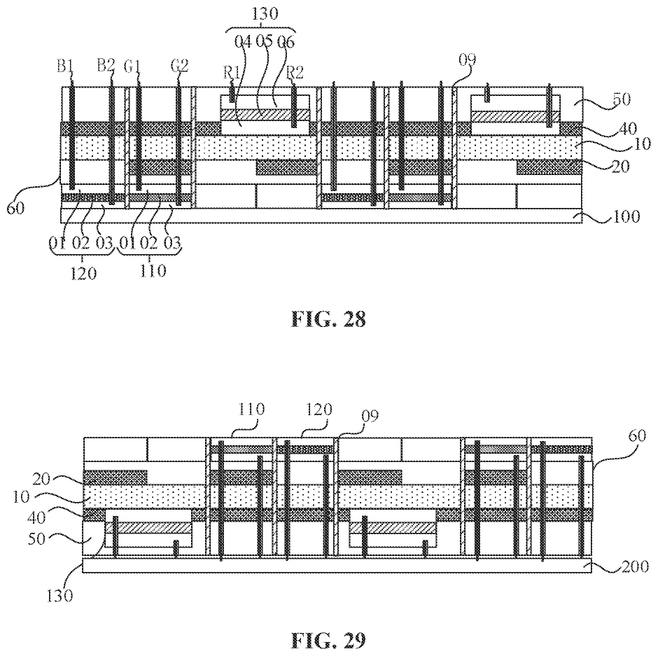

Illustratively, referring to FIG. 28, a first external lead positive electrode B1 and a first external lead negative electrode B2 of the first light-emitting unit 110 are prepared; a second external lead positive electrode G1 and a second external lead negative electrode G2 of the second light-emitting unit 120 are prepared; a third external lead positive electrode R1 and a third external lead negative electrode R2 of the third light-emitting unit 130 are prepared. For the preparation process, reference may be made to step S2100, and the details are not repeated here.

In S4110, the first light-emitting units, the second light-emitting units, and the third light-emitting units are transferred to the driving substrate through the transposition substrate, and external lead electrodes are connected to connection contact points on the driving substrate in a one-to-one manner.

Illustratively, referring to FIG. 29, the first light-emitting units 110, the second light-emitting units 120, and the third light-emitting units 130 are transferred to the driving substrate 200 through the transposition substrate 100, and external lead electrodes are connected to connection contact points on the driving substrate 200 in a one-to-one manner.

On the basis of the preceding embodiments, referring to FIGS. 28 and 29, optionally, after multiple third light-emitting units 130 are epitaxially formed on the back surface of the substrate 10, the method also includes the step below.

A second insulating bank 09 is formed between adjacent first light-emitting unit 110 and second light-emitting unit 120 to prevent electrical signal crosstalk between the first light-emitting unit 110 and the second light-emitting unit 120. When the second insulating bank 09 is made of an opaque material, light crosstalk between light-emitting units may be prevented.

Optionally, a second insulating bank 09 is formed between adjacent second light-emitting unit 120 and third light-emitting unit 130, a second insulating bank 09 is formed between an adjacent third light-emitting unit 130 and first light-emitting unit 110. In this manner, electrical signal crosstalk between each light-emitting unit is avoided. Optionally, the first insulating bank 1301 and the second insulating bank 09 may be manufactured simultaneously. Optionally, part of the first insulating bank 1301 may serve as the second insulating bank 09.

It is to be noted that in the preceding embodiment, the front surface process of the substrate and the back surface process of the substrate may be combined arbitrarily.

An embodiment of the present disclosure provides a light-emitting device formed by the manufacturing method of a light-emitting device described in any preceding embodiment. Referring to FIG. 13, 19, or 29, the light-emitting device includes a substrate 10, a first mask layer 20, multiple first light-emitting units 110 and multiple second light-emitting units 120, and third light-emitting units 130.

The substrate 10 includes a front surface and a back surface opposite to each other.

The first mask layer 20 includes multiple front mask openings.

The multiple first light-emitting units 110 and multiple second light-emitting units 120 are located on the front surface of the substrate 10. The component proportion of the first element in the first light-emitting units 110 is different from the component proportion of the first element in the second light-emitting units 120.

The third light-emitting units 130 are located on the back surface of the substrate 10.

In an embodiment of the present disclosure, optionally, referring to FIGS. 13 and 4, the material of the first mask layer 20 includes silicon oxide and/or silicon nitride. The first mask layer 20 includes multiple first front mask openings 201 and multiple second front mask openings 202. The opening area of a first front mask opening 201 is greater than the opening area of a second front mask opening 202. The first light-emitting units 110 are located in the first front mask openings 201. The second light-emitting units 120 are located in the second front mask openings 202.

Alternatively, in an embodiment of the present disclosure, referring to FIGS. 29 and 21, the material of the first mask layer 20 includes aluminum nitride. The first light-emitting units 110 are located in the non-opening region of the first mask layer 20. The second light-emitting units 120 are located in the front mask openings 210.

On the basis of the preceding embodiments, optionally, the back surface of the substrate 10 includes multiple grooves. The third light-emitting units 130 are located in the grooves.

Alternatively, referring to FIGS. 13 and 9, the back surface of the substrate 10 is provided with the second mask layer 40. The second mask layer 40 includes multiple back mask openings 401 exposing the substrate 10. The third light-emitting unit 130 is located in the back mask openings 401.

Alternatively, referring to FIGS. 19 and 16, the back surface of the substrate 10 includes a third light-emitting unit epitaxial layer 1300. An annular first insulating bank 1301 is disposed around the preset position corresponding to each third light-emitting unit 130 in the third light-emitting unit epitaxial layer 1300. The third light-emitting unit epitaxial layer 1300 surrounded by the first insulating bank 1301 is configured to constitute a third light-emitting unit 130.

It is to be noted that the preceding are only preferred embodiments of the present disclosure and technical principles used therein. It is to be understood by those skilled in the art that the present disclosure is not limited to the embodiments described herein. Those skilled in the art can make various apparent modifications, adaptations, and substitutions without departing from the scope of the present disclosure. Therefore, while the present disclosure has been described in detail through the preceding embodiments, the present disclosure is not limited to the preceding embodiments and may include more other equivalent embodiments without departing from the concept of the present disclosure. The scope of the present disclosure is determined by the scope of the appended claims.

What is claimed is:

1. A manufacturing method of a light-emitting device, comprising:
providing a substrate comprising a front surface and a back surface opposite to each other,
forming a first mask layer on the front surface of the substrate and forming a front mask opening in the first mask layer by performing patterning process on the first mask layer;
growing a semiconductor epitaxial layer on the front surface of the substrate based on the first mask layer after the patterning process, and doping a first element during growth of the semiconductor epitaxial layer to form a first light-emitting unit and a second light-emitting unit, wherein a component proportion of the first element in the first light-emitting unit is different from a component proportion of the first element in the second light-emitting unit;
turning the substrate upside down on a transposition substrate to expose the back surface of the substrate; and
forming a third light-emitting unit on the back surface of the substrate.

2. The manufacturing method according to claim 1, wherein a material of the first mask layer comprises silicon oxide and/or silicon nitride; and the forming the front mask opening comprises:
etching the first mask layer to form a first front mask opening and a second front mask opening, wherein an opening area of the first front mask opening is greater than an opening area of the second front mask opening; and
forming the first light-emitting unit and the second light-emitting unit comprises:
forming a first semiconductor layer, a first active layer, and a second semiconductor layer in sequence in the first front mask opening and in the second front mask opening, and doping the first element when forming the first active layer to form the first light-emitting unit in the first front mask opening and the second light-emitting unit in the second front mask opening, wherein the component proportion of the first element in the first light-emitting unit is different from the component proportion of the first element in the second light-emitting unit.

3. The manufacturing method according to claim 1, wherein a material of the first mask layer comprises aluminum nitride; and
forming the first light-emitting unit and the second light-emitting unit comprises:
forming a first semiconductor layer, a first active layer, and a second semiconductor layer in sequence in the front mask opening and on a side of the first mask layer facing away from the substrate and doping the first element when forming the first active layer to form the first light-emitting unit on the side of the first mask layer facing away from the substrate and the second light-emitting unit in the front mask opening, wherein the component proportion of the first element in the first light-emitting unit is different from the component proportion of the first element in the second light-emitting unit.

4. The manufacturing method according to claim 3, before forming the first light-emitting unit and the second light-emitting unit, further comprising:
forming a buffer layer in the front mask opening of the first mask layer and on the side of the first mask layer facing away from the substrate, wherein a surface of the buffer layer on a side facing away from the substrate is a plane surface.

5. The manufacturing method according to claim 2, wherein before turning the substrate upside down on the transposition substrate, further comprising:
forming a first passivation layer on the front surface of the substrate, wherein the first passivation layer at least covers a surface of the first light-emitting unit and the second light-emitting unit.

6. The manufacturing method according to claim 2, wherein forming the third light-emitting unit on the back surface of the substrate comprises:
etching the back surface of the substrate to form a groove; and
forming a third semiconductor layer, a second active layer, and a fourth conductor layer in sequence in the groove to form the third light-emitting unit on the back surface of the substrate.

7. The manufacturing method according to claim 2, wherein forming the third light-emitting unit on the back surface of the substrate comprises:
forming a second mask layer on the back surface of the substrate;
etching the second mask layer to form a back mask opening exposing the substrate; and
forming a third semiconductor layer, a second active layer, and a fourth semiconductor layer in sequence in the back mask opening to form the third light-emitting unit on the back surface of the substrate.

8. The manufacturing method according to claim 2, wherein forming the third light-emitting unit on the back surface of the substrate comprises:
depositing a third semiconductor layer, a second active layer, and a fourth conductor layer in sequence on the back surface of the substrate to form a third light-emitting unit epitaxial layer;
etching the third light-emitting unit epitaxial layer to form an annular surrounding groove at an edge of a preset position corresponding to the third light-emitting unit in the third light-emitting unit epitaxial layer; and
filling an insulating material in the annular surrounding groove to form a first insulating bank, wherein a third semiconductor layer, a second active layer, and a fourth semiconductor layer surrounded by the first insulating bank are configured to form the third light-emitting unit.

9. The manufacturing method according to claim 1, before forming the third light-emitting unit on the back surface of the substrate, further comprising:
thinning the substrate from the back surface of the substrate.

10. The manufacturing method according to claim 1, after forming the third light-emitting unit on the back surface of the substrate, further comprising:
forming a second insulating bank between adjacent first light-emitting unit and second light-emitting unit.

11. The manufacturing method according to claim 3, wherein before turning the substrate upside down on the transposition substrate, further comprising:
forming a first passivation layer on the front surface of the substrate, wherein the first passivation layer at least covers a surface of the first light-emitting unit and the second light-emitting unit.

12. The manufacturing method according to claim 4, wherein before turning the substrate upside down on the transposition substrate, further comprising:
forming a first passivation layer on the front surface of the substrate, wherein the first passivation layer at least covers a surface of the first light-emitting unit and the second light-emitting unit.

13. The manufacturing method according to claim 3, wherein forming the third light-emitting unit on the back surface of the substrate comprises:
etching the back surface of the substrate to form a groove; and
forming a third semiconductor layer, a second active layer, and a fourth conductor layer in sequence in the groove to form the third light-emitting unit on the back surface of the substrate.

14. The manufacturing method according to claim 4, wherein forming the third light-emitting unit on the back surface of the substrate comprises:
etching the back surface of the substrate to form a groove; and
forming a third semiconductor layer, a second active layer, and a fourth conductor layer in sequence in the groove to form the third light-emitting unit on the back surface of the substrate.

15. The manufacturing method according to claim 3, wherein forming the third light-emitting unit on the back surface of the substrate comprises:
forming a second mask layer on the back surface of the substrate;
etching the second mask layer to form a back mask opening exposing the substrate; and
forming a third semiconductor layer, a second active layer, and a fourth semiconductor layer in sequence in the back mask opening to form the third light-emitting unit on the back surface of the substrate.

16. The manufacturing method according to claim 4, wherein forming the third light-emitting unit on the back surface of the substrate comprises:
forming a second mask layer on the back surface of the substrate;
etching the second mask layer to form a back mask opening exposing the substrate; and
forming a third semiconductor layer, a second active layer, and a fourth semiconductor layer in sequence in the back mask opening to form the third light-emitting unit on the back surface of the substrate.

17. The manufacturing method according to claim 3, wherein forming the third light-emitting unit on the back surface of the substrate comprises:
depositing a third semiconductor layer, a second active layer, and a fourth conductor layer in sequence on the back surface of the substrate to form a third light-emitting unit epitaxial layer;
etching the third light-emitting unit epitaxial layer to form an annular surrounding groove at an edge of a preset position corresponding to the third light-emitting unit in the third light-emitting unit epitaxial layer; and
filling an insulating material in the annular surrounding groove to form a first insulating bank, wherein a third semiconductor layer, a second active layer, and a fourth semiconductor layer surrounded by the first insulating bank are configured to form the third light-emitting unit.

18. A light-emitting device, comprising:
a substrate comprising a front surface and a back surface opposite to each other;
a first mask layer comprising a front mask opening;
a first light-emitting unit and a second light-emitting unit located on the front surface of the substrate, wherein a component proportion of a first element in the first light-emitting unit is different from a component proportion of the first element in the second light-emitting unit; and
a third light-emitting unit located on the back surface of the substrate.

19. The light-emitting device according to claim 18, wherein
a material of the first mask layer comprises silicon oxide and/or silicon nitride, the first mask layer comprises a first front mask opening and a second front mask opening, and an opening area of the first front mask opening is greater than an opening area of the second front mask opening; and the first light-emitting unit is located in the first front mask opening, and the second light-emitting unit is located in the second front mask opening; or
a material of the first mask layer comprises aluminum nitride; and the first light-emitting unit is located in a non-opening region of the first mask layer, and the second light-emitting unit is located in the front mask opening.

20. The light-emitting device according to claim 19, wherein
the back surface of the substrate comprises a groove, wherein the third light-emitting unit is located in the groove; or
the back surface of the substrate is provided with a second mask layer, the second mask layer comprises a back mask opening exposing the substrate, and the third light-emitting unit is located in the back mask opening; or
the back surface of the substrate comprises a third light-emitting unit epitaxial layer, and an annular first insulating bank is disposed around a preset position corresponding to the third light-emitting unit in the third light-emitting unit epitaxial layer; and the third light-emitting unit epitaxial layer surrounded by the first insulating bank is configured to constitute the third light-emitting unit.
